(19) United States
(12) Patent Application Publication
(10) Pub. No.: US 2013/0026641 A1
(43) Pub. Date: Jan. 31, 2013

(54) CONDUCTOR CONTACT STRUCTURE AND FORMING METHOD, AND PHOTOMASK PATTERN GENERATING METHOD FOR DEFINING SUCH CONDUCTOR CONTACT STRUCTURE

(71) Applicant: Chin-Sheng YANG, Hsinchu City (TW)

(72) Inventor: Chin-Sheng YANG, Hsinchu City (TW)

(73) Assignee: UNITED MICROELECTRONICS CORP., HSINCHU (TW)

(21) Appl. No.: 13/189,623

(22) Filed: Jul. 25, 2011

(51) Int. Cl. H01L 23/48; G03F 1/14; H01L 21/28

(52) U.S. Cl. 257/774; 438/675; 430/5; 257/E23.011; 257/E21.158

(57) ABSTRACT

A conductor contact structure includes a conductor line, a dielectric layer and a contact hole. The conductor line includes a first zone and a second zone. The first zone extends along a symmetry axis and is symmetrical with respect to the symmetry axis. The second zone extends along the symmetry axis but is not symmetrical with respect to the symmetry axis. A distance between a first edge of the second zone and the symmetry axis is greater than a distance between a second edge of the second zone and the symmetry axis. A contact hole is formed in the dielectric layer and in communication with the second zone. A diameter of the contact hole is smaller than a distance between the first edge and the second edge of the second zone.

### FIELD OF THE INVENTION

The present invention relates to a conductor contact structure and a conductor contact structure forming method, and more particularly to a conductor contact structure and a conductor contact structure forming method applied to a semiconductor device. The present invention further relates to a photomask pattern generation method for defining such a conductor contact structure.

### BACKGROUND OF THE INVENTION

In the fabrication of a semiconductor device, a multilayer interconnection structure is widely used to connect different levels of conductor lines through contact holes and contact plugs. The contact holes are formed in dielectric layers. The contact plugs are inserted into corresponding contact holes. The conductor line, the contact hole and the contact plug may be collectively referred as a conductor contact structure. As the semiconductor device is developed toward miniaturization, the width of the conductor line and the diameter of the contact hole are gradually reduced. Therefore, the difficulty in forming the conductor contact structure is increased.

FIG. 1A is a schematic top view illustrating a mask layout for defining a conductor contact structure. In the mask layout, a first pattern 110 corresponding to a first conductor line and a second pattern 120 corresponding to a second conductor line are arranged beside each other and formed on a photomask. A dielectric layer (not shown) is formed on the first conductor line and a second conductor line. For connecting the first conductor line with another conductor line (not shown) overlying the dielectric layer, a contact hole is formed in the first conductor line. For defining the contact hole, a contact hole pattern 140 is formed on another photomask. Moreover, for providing an alignment tolerance of forming the contact hole during a subsequent photolithography process, two enlarged portions 1100 are formed at bilateral sides of the first pattern 110 at the location corresponding to the contact hole pattern 140.

FIG. 1B is a schematic perspective view illustrating a conductor contact structure defined by the mask layout of FIG. 1A. As shown in FIG. 1B, a first conductor line 910 and a second conductor line 920 are arranged beside each other. A dielectric layer 990 is formed on the first conductor line 910 and a second conductor line 920. Another conductor line 980 is disposed over the dielectric layer 990. In addition, a contact hole 940 is formed in the dielectric layer 990. In the mask layout, the contact hole pattern has a square shape. However, since the photolithography process may result in rounding profile of the conductor lines, the contact hole 940 may also have a rounding profile (see FIG. 1B). Since one of the enlarged portions 9100 of the first conductor line 910 is close to the second conductor line 920, some problem may occur. For example, if the spacing interval between the enlarged portion 9100 and the second conductor line 920 is smaller than an acceptable distance, the enlarged portion 9100 and the second conductor line 920 may be erroneously contacted with each other to result in occurrence of a short-circuited problem. Therefore, there is a need of providing an improved conductor contact structure to obviate the drawbacks encountered from the prior art.

### SUMMARY OF THE INVENTION

In accordance with an aspect, the present invention provides a conductor contact structure. The conductor contact structure includes a conductor line, a dielectric layer and a contact hole. The conductor line includes a first zone and a second zone. The first zone extends along a symmetry axis and is symmetrical with respect to the symmetry axis. The second zone extends along the symmetry axis but is not symmetrical with respect to the symmetry axis. A distance between a first edge of the second zone and the symmetry axis is greater than a distance between a second edge of the second zone and the symmetry axis. The dielectric layer is formed over the conductor line. A contact hole is formed in the dielectric layer and in communication with the second zone. A diameter of the contact hole is smaller than a distance between the first edge and the second edge of the second zone.

In an embodiment, a first side of the second zone further includes an enlarged portion, wherein a border of the enlarged portion is the first edge of the second zone.

In an embodiment, the second edge of the second zone is close to a nearby conductor line, wherein a spacing interval between the second edge of the second zone and the nearby conductor line is smaller than a threshold value.

In an embodiment, a second side of the second zone further comprises an additional enlarged portion, wherein a border of the additional enlarged portion is the second edge of the second zone.

In an embodiment, a center of the contact hole is substantially aligned an equidistant point between the first edge and the second edge of the second zone.

In an embodiment, the conductor contact structure further includes a contact plug, which is inserted into the contact hole.

In accordance with another aspect, the present invention provides a conductor contact structure forming method. The conductor contact structure forming method includes the following steps. Firstly, a substrate is provided. Then, a conductor line is formed over the substrate. The conductor line includes a first zone and a second zone, which are connected with each other. The first zone extends along a symmetry axis and is symmetrical with respect to the symmetry axis. The second zone extends along the symmetry axis but is not symmetrical with respect to the symmetry axis. A distance between a first edge of the second zone and the symmetry axis is greater than a distance between a second edge of the second zone and the symmetry axis. Then, a dielectric layer is formed on the conductor line. Afterwards, a contact hole is formed in the dielectric layer, wherein the contact hole is in communication with the second zone. Moreover, a center of the contact hole is substantially aligned with a center of the second zone, and a diameter of the contact hole is smaller than a distance between the first edge and the second edge of the second zone.

In an embodiment, the step of forming the conductor line over the substrate includes sub-steps of forming a conductor layer over the substrate, and performing a first photolithography process to partially remove the conductor layer, thereby defining the conductor line and a nearby conductor line adjacent to the conductor line. A first side of the second zone of the conductor line further includes an enlarged portion, wherein a border of the enlarged portion is the first edge of the second zone.

In an embodiment, the second edge of the second zone is close to the nearby conductor line, wherein a spacing interval between the second edge of the second zone and the nearby conductor line is smaller than a threshold value.

In an embodiment, a second side of the second zone further includes an additional enlarged portion, wherein a border of the additional enlarged portion is the second edge of the second zone.

In an embodiment, the contact hole is formed in the dielectric layer by a second photolithography process.

In an embodiment, the conductor contact structure forming method further includes a step of forming a contact plug within the contact hole.

In accordance with a further aspect, the present invention provides a photomask pattern generation method. The photomask pattern generation method includes the following steps. Firstly, a first pattern corresponding to a conductor line is formed on a first photomask. The first pattern includes a first zone and a second zone, which are connected with each other. The first zone extends along a symmetry axis and is symmetrical with respect to the symmetry axis. The second zone extends along the symmetry axis but is not symmetrical with respect to the symmetry axis. In addition, a distance between a first edge of the second zone and the symmetry axis is greater than a distance between a second edge of the second zone and the symmetry axis. Then, a second pattern corresponding to a contact hole is formed on a second photomask. Moreover, a center of the second pattern is substantially aligned with a center of the second zone of the first mask, and a diameter of the second pattern is smaller than a distance between the first edge and the second edge of the second zone.

In an embodiment, the step of forming the first pattern on the first photomask includes the following sub-steps. Firstly, a contact hole connection region in the first photomask is located. Then, the contact hole connection region is enlarged, thereby forming two enlarged portions at bilateral sides of the contact hole connection region. If a spacing interval between the conductor line and a nearby conductor line is smaller than a threshold value, the enlarged portion adjacent to the nearby conductor line is partially or completely removed, thereby forming a partially-enlarged contact hole connection region corresponding to the second zone of the first pattern.

In an embodiment, the step of forming the second pattern on the second photomask includes sub-steps of aligning a center of the second pattern with a center of the partially-enlarged contact hole connection region, and adjusting a diameter of the second pattern to be smaller than a distance between a first edge and a second edge the partially-enlarged contact hole connection region.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic top view illustrating a mask layout for defining a conductor contact structure;

FIG. 1B is a schematic perspective view illustrating a conductor contact structure defined by the mask layout of FIG. 1A;

FIG. 2 is a schematic top view illustrating a mask layout for defining a conductor contact structure according to a first embodiment of the present invention;

FIG. 3A is a schematic top view illustrating a mask layout for defining a conductor contact structure according to another embodiment of the present invention;

FIG. 3B is a schematic top view illustrating a mask layout for defining a conductor contact structure according to a further embodiment of the present invention;

FIG. 4A is a schematic cross-sectional view illustrating a conductor line formed on a substrate during a process of forming a conductor contact structure according to an embodiment of the present invention;

FIG. 4B is a schematic top view illustrating the conductor line as shown in FIG. 4A;

FIG. 4C is a schematic cross-sectional view illustrating a dielectric layer and an etch mask formed over the conductor line during the process of forming the conductor contact structure according to an embodiment of the present invention; and

FIG. 5 is a flowchart illustrating a photomask pattern generation method according to an embodiment of the present invention.

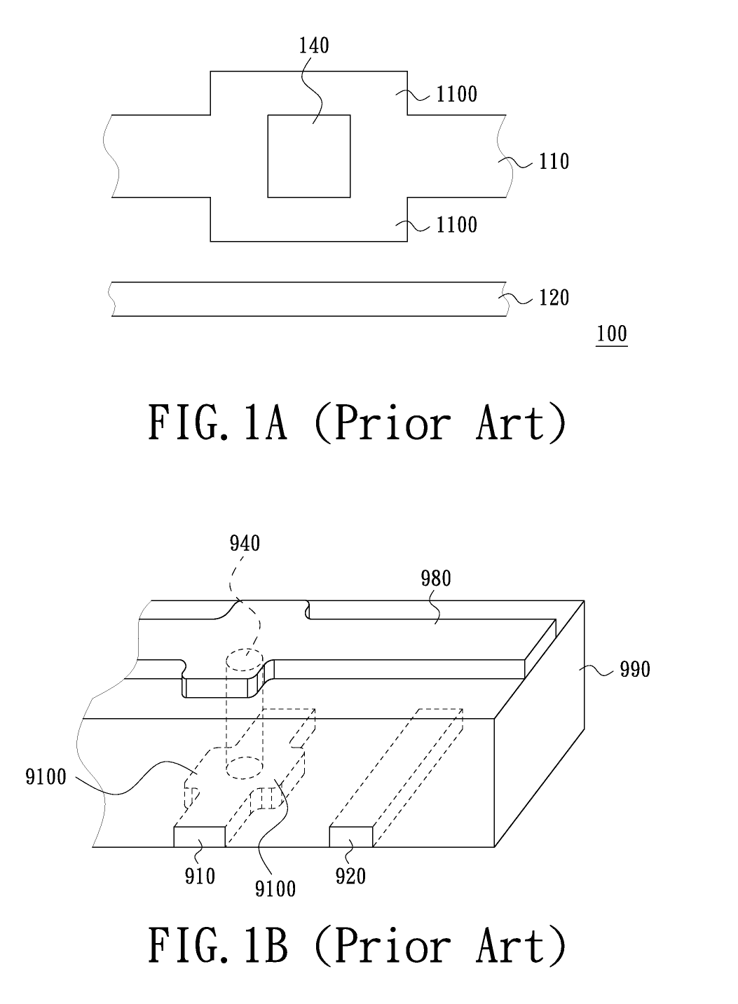

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

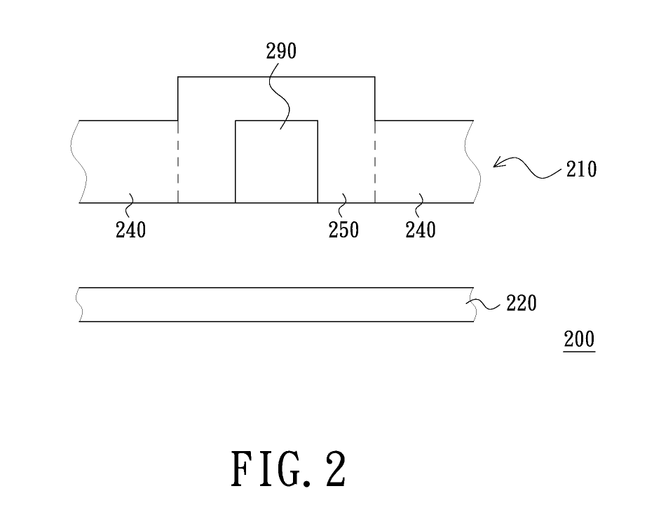

FIG. 2 is a schematic top view illustrating a mask layout for defining a conductor contact structure according to a first embodiment of the present invention. The conductor contact structure pattern 200 comprises a conductor line pattern 210 and a contact hole pattern 290. The conductor line pattern 210 is configured for defining a metallic conductor line. The contact hole pattern 290 is configured for defining a contact hole in a dielectric layer (not shown). For avoiding the drawbacks encountered from the prior art, if the distance between the conductor line pattern 210 and a nearby conductor line pattern 220, the contact hole connection region of the conductor line pattern 210 is modified according to the technology of the present invention. In this embodiment, the enlarged portion of the conductor line pattern 210 close to the nearby conductor line pattern 220 is removed, but the enlarged portion of the conductor line pattern 210 distant from the nearby conductor line 220 is retained. The conductor line pattern 210 comprises a first zone 240 and a second zone 250. The first zone 240 and the second zone 250 are connected with each other. Since the enlarged portion close to the nearby conductor line pattern 220 is completely removed, the short-circuited problem resulting from the small distance between the second zone 250 of the conductor line pattern 210 and the nearby conductor line pattern 220 will be minimized. However, since the contact hole pattern 290 is very close to the edge of the conductor line pattern 210, the contact hole connection region fails to provide an alignment tolerance of forming the contact hole during the subsequent photolithography process.

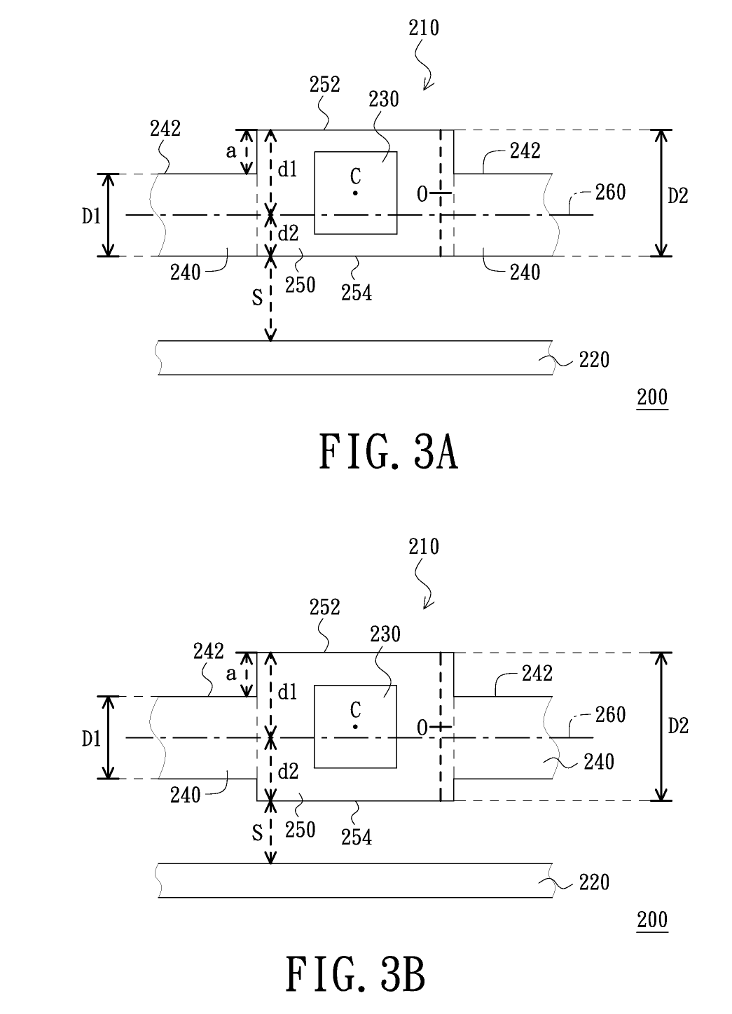

FIG. 3A is a schematic top view illustrating a mask layout for defining a conductor contact structure according to another embodiment of the present invention. As shown in FIG. 3A, the conductor contact structure pattern 200 comprises a conductor line pattern 210 and a contact hole pattern 230. The conductor line pattern 210 is configured for defining a metallic conductor line. The contact hole pattern 230 is configured for defining a contact hole in a dielectric layer (not shown). For avoiding the drawbacks encountered from the prior art, if the distance between the conductor line pattern 210 and a nearby conductor line pattern 220, the contact hole connection region of the conductor line pattern 210 is modified according to the technology of the present invention. In this embodiment, the enlarged portion of the conductor line pattern 210 close to the nearby conductor line pattern 220 is removed, but the enlarged portion of the conductor line pattern 210 distant from the nearby conductor line 220 is retained. The conductor line pattern 210 comprises a first zone 240 and a second zone 250. The first zone 240 and the second zone 250 are connected with each other. The first zone 240 extends along a symmetry axis 260, and is symmetrical with respect to the symmetry axis 260. The second zone 250 also extends along the symmetry axis 260, but is not symmetrical with respect to the symmetry axis 260. The distance d1 between a first edge 252 of the second zone 250 and the symmetry axis 260 is greater than the distance d2 between a second edge 254 of the second zone 250 and the symmetry axis 260. Since the enlarged portion of the conductor line pattern 210 distant from the nearby conductor line 220 is retained, the area of the contact hole connection region is sufficient to provide an alignment tolerance of forming the contact hole during the subsequent photolithography process. Moreover, since the enlarged portion close to the nearby conductor line pattern 220 is completely removed, the short-circuited problem resulting from the small distance between the second edge 254 of the second zone 250 and the nearby conductor line pattern 220 will be minimized.

FIG. 3B is a schematic top view illustrating a mask layout for defining a conductor contact structure according to a further embodiment of the present invention. In this embodiment, the enlarged portion of the conductor line pattern 210 close to the nearby conductor line pattern 220 is partially removed. In such way, the conductor contact structure of this embodiment also has the benefits similar to the mask layout of FIG. 3A.

In the above embodiments, the area of the contact hole connection region (i.e. the second zone 250) is reduced when compared with the prior art technology. For maintaining the alignment tolerance between the contact hole pattern 230 and the conductor line pattern 210, a center C of the contact hole pattern 230 is substantially aligned with an equidistant point O between the first edge 252 and the second edge 254 of the second zone 250. Preferably, the equidistant point O is the center of the second zone 250. In addition, the diameter of the contact hole pattern 230 is smaller than the distance between the first edge 252 and the second edge 254 of the second zone 250.

It is noted that the first edge 252 and the second edge 254 of the second zone 250 are parallel with the symmetry axis 260. The width D2 of the second zone 250 is greater than the width D1 of the first zone 240. The distance d1 between the first edge 252 of the second zone 250 and the symmetry axis 260 is greater than the distance d2 between the second edge 254 of the second zone 250 and the symmetry axis 260. Moreover, the spacing interval S between the second edge 254 of the second zone 250 and the nearby conductor line pattern 220 is greater than a threshold value. In such way, the short-circuited problem resulting from the small distance between the second edge 254 of the second zone 250 and the nearby conductor line pattern 220 will be minimized.

In the above embodiments, the center C of the contact hole 230 is substantially aligned with the equidistant point O between the first edge 252 and the second edge 254 of the second zone 250. However, the location of the center of the contact hole pattern 230 may be slightly deviated from the equidistant point O. For example, in a case that the vertical distance between the first edge 252 of the second zone 250 is a, the location of the center C of the contact hole 230 may be deviated from the equidistant point O by a vertical distance smaller than a/2.

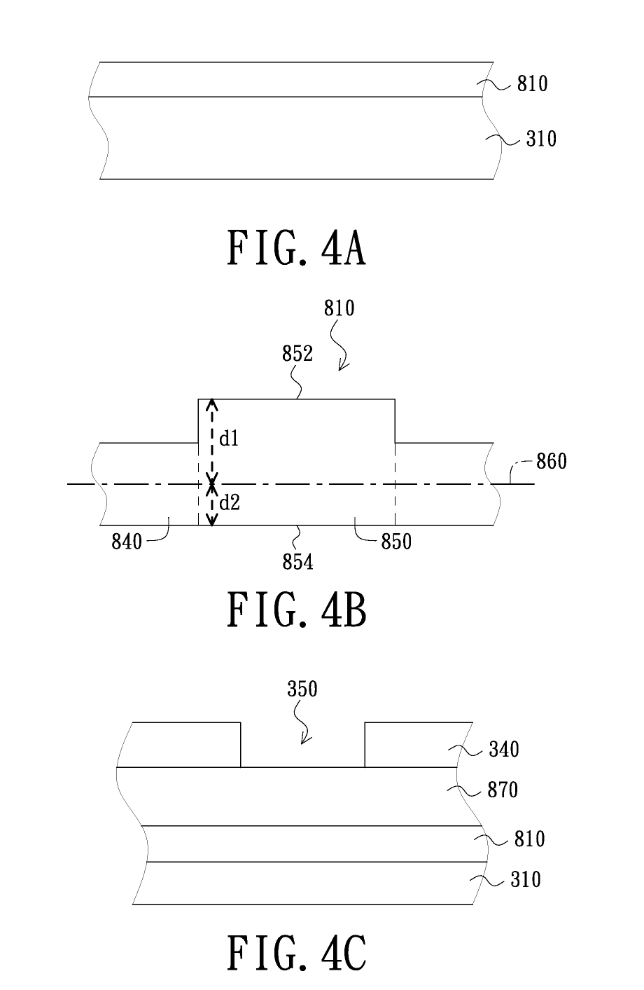

Hereinafter, a process of forming a conductor contact structure by utilizing the mask layout 200 will be illustrated with reference to FIGS. 4A˜4C.

FIG. 4A is a schematic cross-sectional view illustrating a conductor line formed on a substrate during a process of forming a conductor contact structure according to an embodiment of the present invention. Firstly, as shown in FIG. 4A, a substrate 310 is provided. Then, a photolithography process is performed to define a conductor line 810 on the substrate 310.

The top view of the conductor line 810 is shown in FIG. 4B. The conductor line 810 comprises a first zone 840 and a second zone 850. The first zone 840 and the second zone 850 are connected with each other. The first zone 840 extends along a symmetry axis 860, and is symmetrical with respect to the symmetry axis 860. The second zone 850 also extends along the symmetry axis 860, but is not symmetrical with respect to the symmetry axis 860. The distance d1 between a first edge 852 of the second zone 850 and the symmetry axis 860 is greater than the distance d2 between a second edge 854 of the second zone 850 and the symmetry axis 860.

FIG. 4C is a schematic cross-sectional view illustrating a dielectric layer and an etch mask formed over the conductor line during the process of forming the conductor contact structure according to an embodiment of the present invention. After the conductor line 810 is formed, a dielectric layer 870 is formed on the conductor line 810. Then, another photolithography process is performed to define an etch mask 340. The etch mask 340 has an etching window 350. The center of the etching window 350 is substantially aligned with the equidistant point O between the first edge 852 and the second edge 854 of the second zone 850. Then, an etching process is performed to remove the dielectric layer 870 uncovered by the etch mask 340. As a consequence, a contact hole (not shown) is created. The contact hole is in communication with the second zone 850 of the conductor line 810.

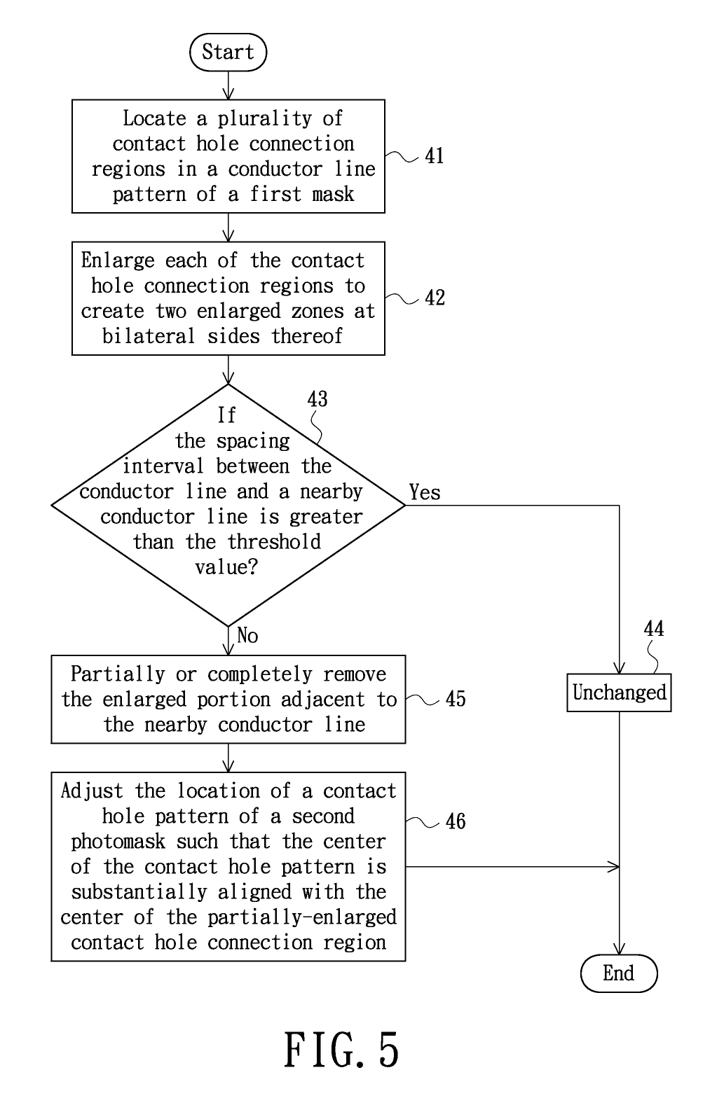

In the above embodiments, the shapes and positions of the conductor line and the contact hole are defined by photolithography processes. Moreover, the photomask patterns for performing the photolithography processes may be automatically generated by a computer program. Hereinafter, a photomask pattern generation method will be illustrated with reference to FIG. 5.

FIG. 4 is a flowchart illustrating a photomask pattern generation method according to an embodiment of the present invention. Firstly, in the step 41, a conductor line pattern corresponding to a conductor line is formed on a first photomask, wherein a plurality of contact hole connection regions are located in the conductor line pattern. Then, in the step 42, each of the contact hole connection regions is enlarged to create two enlarged zones at bilateral sides thereof. Then, a step 43 is performed to judge whether the spacing interval between the conductor line and a nearby conductor line is greater than a threshold value. If the spacing interval between the conductor line and the nearby conductor line is greater than the threshold value, the first pattern is accepted (Step 44). Whereas, if the spacing interval between the conductor line and the nearby conductor line is smaller than the threshold value, the enlarged zone adjacent to the nearby conductor line is partially or completely removed, thereby forming a partially-enlarged contact hole connection region (Step 45). Then, in the step 46, a contact hole pattern corresponding to a contact hole is formed on a second photomask, and the location of second pattern is precisely adjusted such that the center of the contact hole pattern is substantially aligned with the center of the partially-enlarged contact hole connection region. By using the first photomask and the second photomask, a corresponding conductor contact structure can be produced.

From the above description, the conductor contact structure of the present invention has many benefits. Since the center of the contact hole is substantially aligned with the center of the second zone of the conductor line and the diameter of the contact hole is smaller than the distance between the first edge and the second edge of the second zone, the short-circuited problem resulting from the small distance between the conductor line and the nearby conductor line will be eliminated and the size of the contact hole is still satisfied. In the subsequent process, a contact plug may be inserted into the contact hole to be electrically connected with the conductor line. In such way, the purpose of implementing a multilayer interconnection structure will be achievable.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A conductor contact structure, comprising:
a conductor line comprising a first zone and a second zone, which are connected with each other, wherein the first zone extends along a symmetry axis and is symmetrical with respect to the symmetry axis, and the second zone extends along the symmetry axis but is not symmetrical with respect to the symmetry axis, wherein a distance between a first edge of the second zone and the symmetry axis is greater than a distance between a second edge of the second zone and the symmetry axis;
a dielectric layer formed over the conductor line; and
a contact hole formed in the dielectric layer and in communication with the second zone, wherein a diameter of the contact hole is smaller than a distance between the first edge and the second edge of the second zone.

2. The conductor contact structure according to claim 1, wherein a first side of the second zone further comprises an enlarged portion, wherein a border of the enlarged portion is the first edge of the second zone.

3. The conductor contact structure according to claim 2, wherein the second edge of the second zone is close to a nearby conductor line, wherein a spacing interval between the second edge of the second zone and the nearby conductor line is smaller than a threshold value.

4. The conductor contact structure according to claim 3, wherein a second side of the second zone further comprises an additional enlarged portion, wherein a border of the additional enlarged portion is the second edge of the second zone.

5. The conductor contact structure according to claim 1, wherein a center of the contact hole is substantially aligned an equidistant point between the first edge and the second edge of the second zone.

6. The conductor contact structure according to claim 1, further comprises a contact plug, which is inserted into the contact hole.

7. A conductor contact structure forming method, comprising steps of:
providing a substrate;
forming a conductor line over the substrate, wherein the conductor line comprises a first zone and a second zone, which are connected with each other, wherein the first zone extends along a symmetry axis and is symmetrical with respect to the symmetry axis, and the second zone extends along the symmetry axis but is not symmetrical with respect to the symmetry axis, wherein a distance between a first edge of the second zone and the symmetry axis is greater than a distance between a second edge of the second zone and the symmetry axis;
forming a dielectric layer on the conductor line; and
forming a contact hole in the dielectric layer, wherein the contact hole is in communication with the second zone, wherein a center of the contact hole is substantially aligned with a center of the second zone, and a diameter of the contact hole is smaller than a distance between the first edge and the second edge of the second zone.

8. The conductor contact structure according to claim 7, wherein a center of the contact hole is substantially aligned with an equidistant point between the first edge and the second edge of the second zone.

9. The conductor contact structure forming method according to claim 7, wherein the step of forming the conductor line over the substrate comprises sub-steps of:
forming a conductor layer over the substrate; and
performing a first photolithography process to partially remove the conductor layer, thereby defining the conductor line and a nearby conductor line adjacent to the conductor line, wherein a first side of the second zone of the conductor line further comprises an enlarged portion, wherein a border of the enlarged portion is the first edge of the second zone

10. The conductor contact structure forming method according to claim 9, wherein the second edge of the second zone is close to the nearby conductor line, wherein a spacing interval between the second edge of the second zone and the nearby conductor line is smaller than a threshold value.

11. The conductor contact structure forming method according to claim 10, wherein a second side of the second zone further comprises an additional enlarged portion, wherein a border of the additional enlarged portion is the second edge of the second zone.

12. The conductor contact structure forming method according to claim 7, wherein the contact hole is formed in the dielectric layer by a second photolithography process.

13. The conductor contact structure forming method according to claim 7, further comprising a step of forming a contact plug within the contact hole.

14. A photomask pattern generation method, comprising steps of:
forming a first pattern corresponding to a conductor line on a first photomask, wherein the first pattern comprises a first zone and a second zone, which are connected with each other, wherein the first zone extends along a symmetry axis and is symmetrical with respect to the symmetry axis, and the second zone extends along the symmetry axis but is not symmetrical with respect to the symmetry axis, wherein a distance between a first edge of the second zone and the symmetry axis is greater than a distance between a second edge of the second zone and the symmetry axis; and
forming a second pattern corresponding to a contact hole on a second photomask, wherein a center of the second pattern is substantially aligned with a center of the second zone of the first mask, and a diameter of the second pattern is smaller than a distance between the first edge and the second edge of the second zone.

15. The photomask pattern generation method according to claim 14, wherein the step of forming the first pattern on the first photomask comprises sub-steps of:
locating a contact hole connection region in the first photomask;
enlarging the contact hole connection region, thereby forming two enlarged portions at bilateral sides of the contact hole connection region; and
if a spacing interval between the conductor line and a nearby conductor line is smaller than a threshold value, partially or completely removing the enlarged portion adjacent to the nearby conductor line, thereby forming a partially-enlarged contact hole connection region corresponding to the second zone of the first pattern.

16. The photomask pattern generation method according to claim 15, wherein the step of forming the second pattern on the second photomask comprises a sub-step of aligning a center of the second pattern with a center of the partially-enlarged contact hole connection region.
